(19) United States
(12) Patent Application Publication
(10) Pub. No.: US 2021/0127769 A1
(43) Pub. Date: May 6, 2021

(54) THERMOELECTRIC COOLER HEADBAND

(71) Applicant: Prolivio Corp., Rochester, NY (US)

(72) Inventors: Benjamin ZOMBEK, Pittsford, NY (US); Robert D. JUNCOSA, Williamsburg, VA (US); Adam BAKER, Rochester, NY (US)

(73) Assignee: Prolivio Corp., Rochester, NY (US)

(21) Appl. No.: 17/084,175

(22) Filed: Oct. 29, 2020

Related U.S. Application Data
(60) Provisional application No. 62/927,943, filed on Oct. 30, 2019.

(51) Int. Cl. A41D 20/00; H01L 35/30; H01L 35/32; H01L 25/04; F25B 21/02

(52) U.S. Cl. CPC A41D 20/005; H01L 35/30; F25B 21/02; H01L 25/04; H01L 35/32

(57) ABSTRACT

A thermoelectric cooler (TEC) headband operable to fit around a user's head. The TEC headband includes a pair of TEC devices spaced apart a predetermined distance. The predetermined distance is sized to position the TEC devices on either side of a forehead of the user. Each TEC device includes a cooling plate and a heating plate. The TEC devices are operable, via a Peltier effect, to conduct heat from the cooling plate to the heating plate when a current is conducted therethrough. A pair of heat sinks are positioned in thermal contact with the heating plate of each TEC device. Each heat sink is operable to conduct heat away from its associated heating plate. A housing is operable to contain the pair of TEC devices and pair of heat sinks. The TEC headband is operable to cool the user's forehead when placed thereon.

### CROSS-REFERENCE TO RELATED APPLICATION

This patent application perfects and claims priority benefit to U.S. Provisional Patent Application No. 62/927,943, filed Oct. 30, 2019, and entitled WEARABLE HEATING/COOLING HEADBAND DEVICE, which is hereby incorporated herein by reference in its entirety.

### TECHNICAL FIELD

The present disclosure relates to headbands designed to mitigate migraine pain of a user. More specifically, the disclosure relates to the use of thermoelectric cooler (TEC) devices in headbands for the purpose of same.

### BACKGROUND

A migraine can cause severe throbbing pain or a pulsing sensation in the head, usually on one side. It is often accompanied by nausea, vomiting and extreme sensitivity to light and sound. Migraines can last for any duration from hours to days, and the pain can be so severe that it interferes with the ability to carry out daily activities.

Various medications are available to treat a migraine, which may be prescribed or are available over the counter. However, such medications can be expensive and may have side effects.

Cooling by means of ice packs or frozen gel packs applied to a user's forehead have been used to alleviate the symptoms of a migraine. However, such packs have little to no temperature control and often cause excessive condensation. Further, ice packs or gel packs warm over time, thereby reducing their effectiveness. Additionally, the ice or gel packs may be too cold for a particular user and, therefore, may cause more discomfort than relief over time.

Accordingly, there is a need for a cooling device and method for treating a migraine that maintains a regulated substantially constant set temperature. Additionally, there is a need for cooling devices and methods for treating migraines that can be set at more than one temperature in order to meet the preferences of an individual user. Moreover, there is a need for such devices and method that prevents or substantially reduces the production of condensation.

### BRIEF DESCRIPTION

The present disclosure offers advantages and alternatives over the prior art by providing a thermoelectric cooler (TEC) headband that is operable to fit over a user's head. The TEC headband provides regulated, substantially constant cooling to the forehead of the user. The TEC headband includes a pair of TEC devices that operate via the Peltier effect. When the TEC headband is worn by a user, the TEC devices are positioned directly over the supratrochlear artery and supraorbital artery for an enhanced remedial effect. The TEC headband may be set to a plurality of temperature settings to meet the preferences of a particular user. The TEC headband may be set at cooling temperatures above the dew point temperature to substantially reduce or prevent condensation on a user's forehead. The TEC headband may communicate with a software application on a communication device through, for example, blue tooth technology, to enable remote control and information storage. Additionally, the TEC headband may include a ramped shutdown of the TEC devices to prevent inadvertent overheating of cooling plates on the TEC device when the TEC devices are being shutdown.

A thermoelectric cooler (TEC) headband operable to fit around a user's head in accordance with one or more aspects of the present disclosure includes a pair of TEC devices spaced apart at predetermined distance. The predetermined distance is sized to position the TEC devices on either side of a forehead of the user. Each TEC device includes a cooling plate and a heating plate. The TEC devices are operable, via a Peltier effect, to conduct heat from the cooling plate to the heating plate when a current is conducted therethrough. A pair of heat sinks are positioned in thermal contact with the heating plate of each TEC device. Each heat sink is operable to conduct heat away from its associated heating plate. A housing is operable to contain the pair of Peltier devices and pair of heat sinks. The TEC headband is operable to cool the user's forehead when placed thereon.

Another thermoelectric cooler (TEC) headband operable to fit around a user's head in accordance with one or more aspects of the present disclosure includes a pair of TEC devices. Each TEC device includes a cooling plate and a heating plate. The TEC devices are operable, via a Peltier effect, to conduct heat from the cooling plate to the heating plate when a current is conducted therethrough. A pair of heat sinks are positioned in thermal contact with the heating plate of each TEC device. Each heat sink is operable to conduct heat away from its associated heating plate. A control system is operable to receive a shutdown signal for the TEC devices. Upon receiving the shutdown signal, the control system is operable to reduce the power through each TEC device from its operating power at the time of receiving the shutdown signal to zero power over a predetermined shutdown time period greater than 5 seconds.

A method of cooling a forehead of a user in accordance with one or more aspects of the present disclosure includes fitting a thermoelectric cooler (TEC) headband operable around a user's head. The TEC headband includes:
a pair of TEC devices spaced apart a predetermined distance sized to position the TEC devices on either side of a forehead of the user, each TEC device including:
   a cooling plate, and
   a heating plate,
   wherein, the TEC device is operable, via a Peltier effect, to conduct heat from the cooling plate to the heating plate when a current is conducted therethrough,
a pair of heat sinks, each heat sink positioned in thermal contact with the heating plate of each TEC device, each heat sink operable to conduct heat away from its associated heating plate, and
a control system, wherein, upon receiving a shutdown signal for the TEC devices, the control system is operable to reduce the power through each TEC device from its operating power at the time of receiving the shutdown signal to zero power over a predetermined shutdown time period greater than 5 seconds.

A cooling temperature setting is selected from a plurality of cooling temperature settings the TEC devices can be regulated to. A user's forehead is cooled at the selected cooling temperature setting. A shutdown signal for the TEC devices is activated. The control system reduces the power through each TEC device from its operating power at the time of activating the shutdown signal to zero power over the predetermined time period.

### DRAWINGS

The disclosure will be more fully understood from the following detailed description taken in conjunction with the accompanying drawings, in which:

FIG. 1 depicts an example of a cross sectional view of a thermoelectric cooler (TEC) device having one n-type semiconductor pillar and one p-type semiconductor pillar that are connected electrically in series and thermally in parallel between a cooling plate and a heating plate, in accordance with aspects described herein;

FIG. 2 depicts an example of a perspective view of a TEC device having a plurality of alternating n-type and p-type semiconductor pillars electrically connected in series and positioned thermally in parallel between a cooling plate and a heating plate, in accordance with aspects described herein;

FIG. 3 depicts an example of an exploded perspective view of a TEC headband having a pair of TEC devices in thermal contact with a pair of heat sinks, in accordance with aspects describe herein;

FIG. 4 depicts an example of a perspective view of the TEC headband of FIG. 3 assembled within a housing, in accordance with aspects described herein;

FIG. 5 depicts an example of a perspective view of a TEC headband fit around a user's and having a fan for flowing air over the pair of heat sinks to enhance the transfer of heat from the heat sinks to the atmosphere, in accordance with aspects described herein;

FIG. 6, depicts an example of a perspective view of a TEC headband fit around a user's head and having the TEC devices positioned directly over supratrochlear and supraorbital arties on either side of the user's forehead, in accordance with aspects described herein;

FIG. 7A, depicts an example of a simplified schematic of battery connected to a control system of a TEC headband, the control system including a power on/off control, a pair of TEC devices, and driver circuits for each TEC device, in accordance with aspects described herein;

FIG. 7B, depicts an example of a simplified schematic of a temperature detection circuit, wherein the temperature detection circuit is included in the control system of FIG. 7A, in accordance with aspects described herein;

FIG. 7C, depicts an example of a simplified schematic of an LED selector circuit, wherein the LED selector circuit is included in the control system of FIG. 7A, in accordance with aspects described herein;

FIG. 7D, depicts an example of a simplified schematic of a microcontroller system, wherein the microcontroller system is included in the control system of FIG. 7A, in accordance with aspects described herein; and

FIG. 8, depicts an example of a flow diagram of a method of cooling a forehead of a user in accordance with one or more aspects described herein.

### DETAILED DESCRIPTION

Certain examples will now be described to provide an overall understanding of the principles of the structure, function, manufacture, and use of the methods, systems, and devices disclosed herein. One or more examples are illustrated in the accompanying drawings. Those skilled in the art will understand that the methods, systems, and devices specifically described herein and illustrated in the accompanying drawings are non-limiting examples and that the scope of the present disclosure is defined solely by the claims. The features illustrated or described in connection with one example may be combined with the features of other examples. Such modifications and variations are intended to be included within the scope of the present disclosure.

The terms “significantly”, “substantially”, “approximately”, “about”, “relatively,” or other such similar terms that may be used throughout this disclosure, including the claims, are used to describe and account for small fluctuations, such as due to variations in processing from a reference or parameter. Such small fluctuations include a zero fluctuation from the reference or parameter as well. For example, they can refer to less than or equal to ±10%, such as less than or equal to ±5%, such as less than or equal to ±2%, such as less than or equal to ±1%, such as less than or equal to ±0.5%, such as less than or equal to ±0.2%, such as less than or equal to ±0.1%, such as less than or equal to ±0.05%.

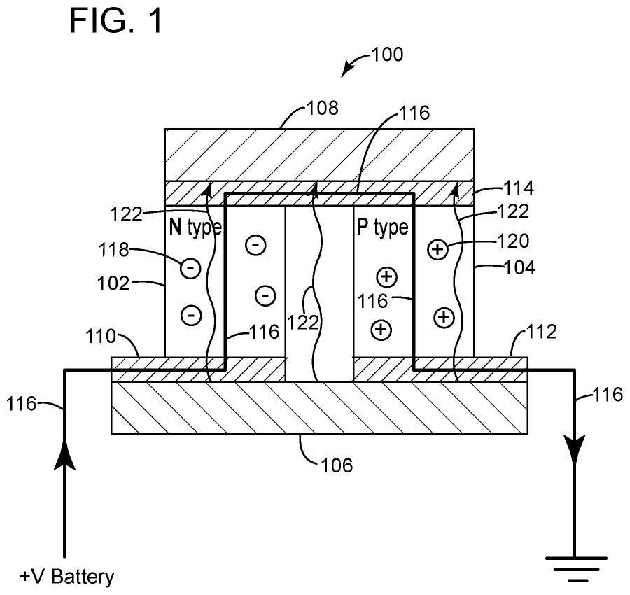

Referring to FIG. 1, an example is depicted of a cross sectional view of a thermoelectric cooler (TEC) device 100 having one n-type semiconductor pillar 102 and one p-type semiconductor pillar 104 that are connected electrically in series and thermally in parallel between a cooling plate 106 and a heating plate 108, in accordance with aspects described herein. The cooling plate 106 and heating plate 108 are insulators that are typically composed of a ceramic material.

A first cold side conductor plate 110 is bonded between the n-type pillar 102 and the cooling plate 106. A second cold side conductor plate 112 is bonded between the p-type pillar 104 and the cooling plate 106. The cold and hot side conductor plates 110, 112 are electrically isolated from each other.

A hot side conductor plate 114 is bonded between the heating plate 108 on one side of the conductor plate 114 and both the n-type and p-type pillars 102, 104 on an opposing side of the conductor plate 114. The hot side conductor plate 114 bridges the n-type and p-type pillars 102, 104 and forms an electrical junction between the two semiconductor pillars 102, 104.

TEC devices (such as TEC device 100) are semiconductor modules that use the Peltier effect to create a temperature gradient between the junction 114 of two materials 102, 104. The Peltier effect shows that a temperature differential is created when a direct current 116 is applied across two different materials (such as the n-type and p-type pillars 102, 104). The n-type semiconductor pillar 102 has an excess of electrons 118, while the p-type semiconductor pillar 104 has an excess of electron holes 120 (or a deficit of electrons). The junction 114 between the n-type and the p-type pillars 102, 104 creates the thermoelectric Peltier effect. The TEC device 100 transfers heat 122 from the cooling plate 106 to the heating plate 108 against a temperature gradient, creating a cooling effect, i.e., the Peltier effect. The more junction couples a TEC device has, the greater its cooling capability.

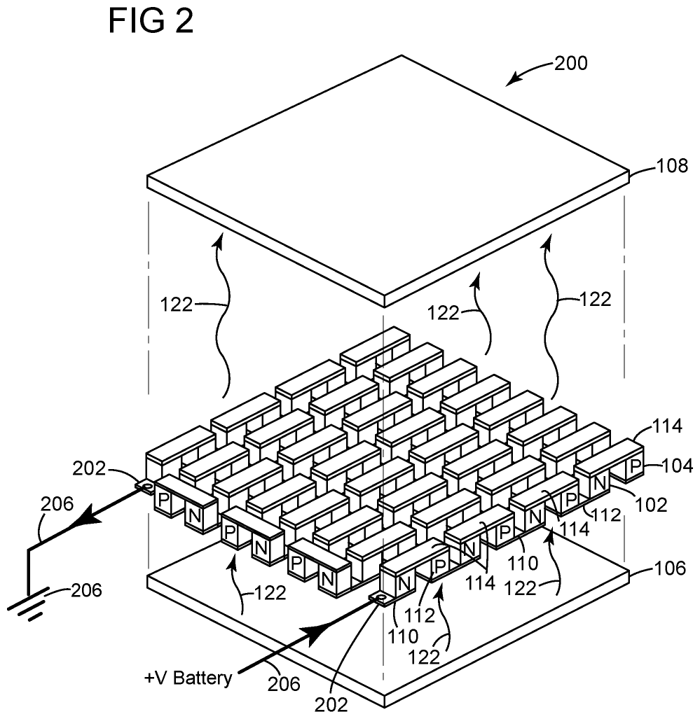

Referring to FIG. 2, an example is depicted of a perspective view of another TEC device 200 having a plurality of alternating n-type 102 and p-type 104 semiconductor pillars electrically connected in series and positioned thermally in parallel between a cooling plate 106 and a heating plate 108, in accordance with aspects described herein. TEC device 200 includes a plurality of alternating n-type and p-type pillars 102, 104, electrically connected is series. In this embodiment of a TEC device 200, the first and second cold side plates 110 and 112 extend between each adjacent pair of n-type and p-type pillars 102, 104 to connect all of the pairs in series. The hot side plates 114 extend over (but not between) each pair of the n-type and p-type pillars 102, 104 to form the electrical junction between the pillars that creates the Peliter effect.

When a voltage differential (such as the voltage differential between Vbattery 204 and ground 206) is applied to the terminal ends 202 of the pairs of semiconductor pillars 102, 104 there is a flow of DC current 206 across each junction 114 of the semiconductors causing a temperature difference. The cooling plate 106 absorbs heat 122 which is then transported by the semiconductors 102, 104 to the heating plate 108 side of the TEC device 200. The cooling ability of the TEC device 200 is then proportional to the total cross section of all the pillars 102, 104.

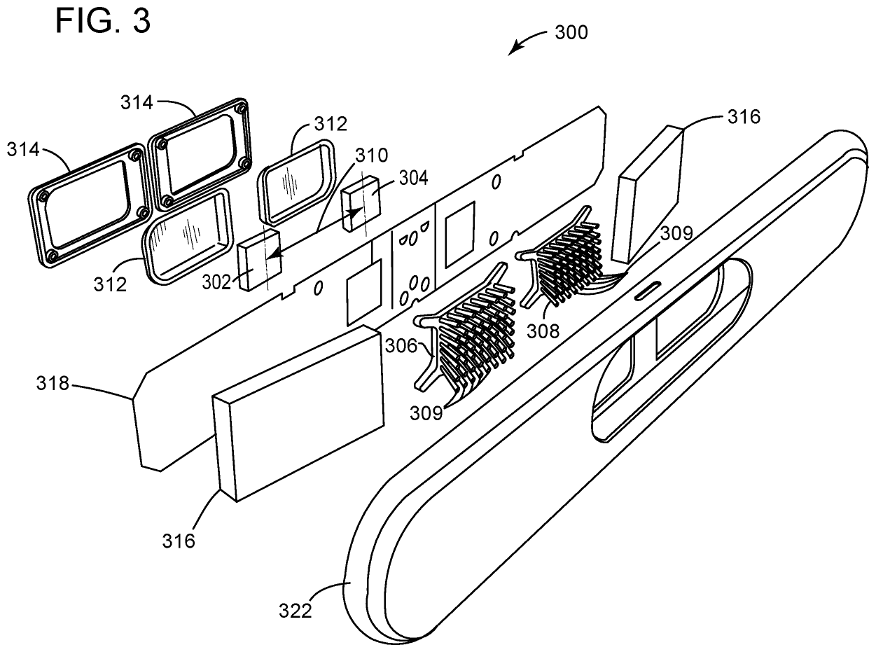

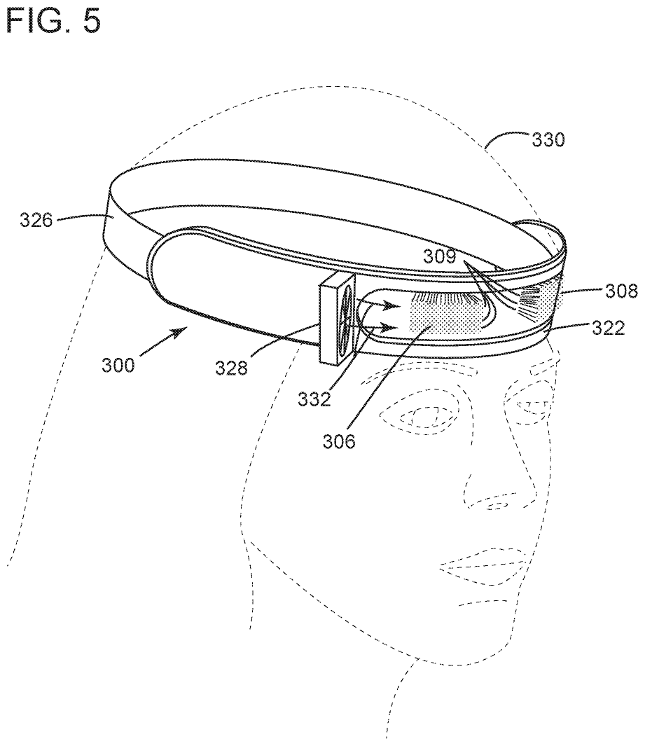

Referring to FIG. 3, an example is depicted of an exploded perspective view of a TEC headband 300 having a pair of TEC devices 302, 304 in thermal contact with a pair of heat sinks 306, 308, in accordance with aspects describe herein. The TEC headband 300 is operable to fit around a head of a user 330 (see FIG. 5).

The TEC devices 302, 304 are spaced apart at their center lines a predetermined distance 310 sized to position the TEC devices 302, 304 on either side of a forehead of the user 330 (see FIG. 5). The predetermined distance 310 may be within a range of 30 to 50 millimeters apart from center line of 302 to centerline of 304.

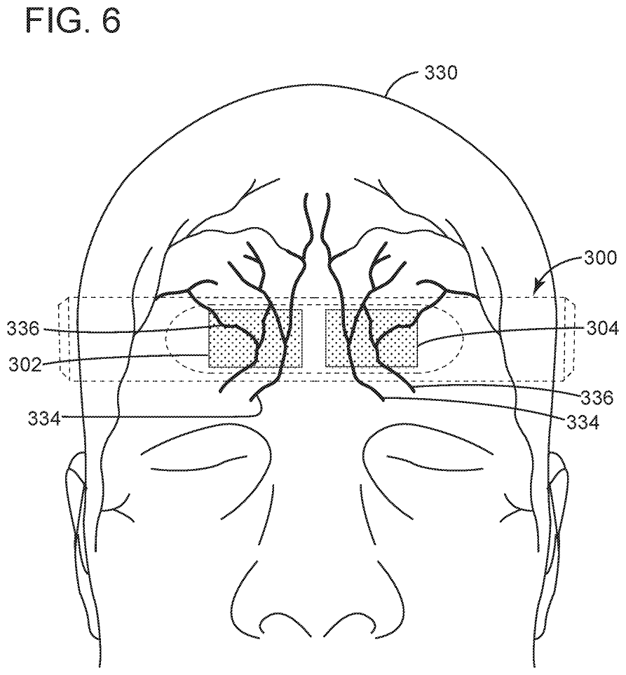

The predetermined distance 310 is designed to place the TEC devices 302, 304 directly over at least one of the supratrochlear and/or supraorbital arteries, located on either side of a users forehead, when the user wears the TEC headband 300 around his or her head (see FIG. 6). Preferably, the predetermined distance 310 separating the TEC devices 302, 304 positions both TEC devices directly over both of the supratrochlear and supraorbital arteries on both sides of the midline of the forehead of a user 330.

The pair of heat sinks 306, 306 are each positioned in thermal contact with a heating plate 108 (see FIG. 2) of each TEC device 302, 304. Each heat sink 306, 308 is operable to conduct heat away from its associated heating plate 108. Each heat sink 306, 308 has a rear surface that is either in direct contact with the heating plate 108 of its associated TEC device 302, 304 or has a thermally conductive material (such as a thermally conductive putty) that enhances the heat transfer between the heating plate 108 and rear surface of the heat sink 306, 308.

Each heat sink 306, 308 has plurality of tubular shaped fins 309 extending outwardly from a top surface on an opposing side relative to the rear surface of the heat sink 306, 308. The tubular fins 309 increase the surface area of the top surface and enhances heat transfer from the heat sinks 306, 308 to the atmosphere. Thought the fins 309 are shown as being generally tubular in shape, they may be configured in other shapes that increase the area of the top surface and, therefore, enhance heat transfer to the atmosphere. For example, the fins may be elongated rectangular fins or elongated wavy shaped fins.

A pair of thermal spreader plates 312 are positioned in thermal contact with the cooling plate 106 (see FIG. 2) of each TEC device 302, 304. The thermal spreader plates 312 may be in direct contact with the cooling plates 106 or may have a thermally conductive material (such as a thermally conductive putty) that enhances the heat transfer between the cooling plate 106 of the heat sinks 306, 308 and the thermal spreader plates 312.

Each thermal spreader plate 312 has a surface area that is larger than a surface area of its associated cooling plate 106, each thermal spreader plate 312 is operable to cool a larger area on a user's forehead than its associated cooling plate 106, when the TEC headband 300 is worn by a user 330. As such, the pain associated with a migraine headache may be more efficiently alleviated. A pair of interface layer frames 314 secure the thermal spreader plates 312 in place within the TEC headband 300.

The TEC headband 300 also includes a pair of batteries 316 that are operable to supply power to the TEC devices 302, 304. Though a pair of batteries is illustrated in FIG. 3, any number of batteries 316 may be used. For example, a single battery 316 may be used, or a stack of more than two batteries 316 may be used.

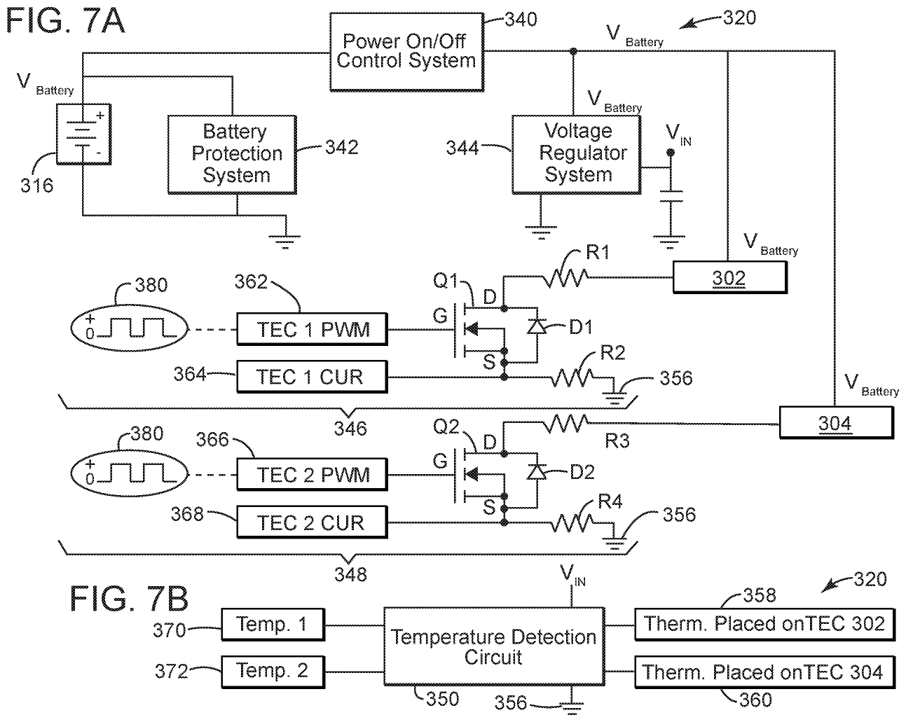

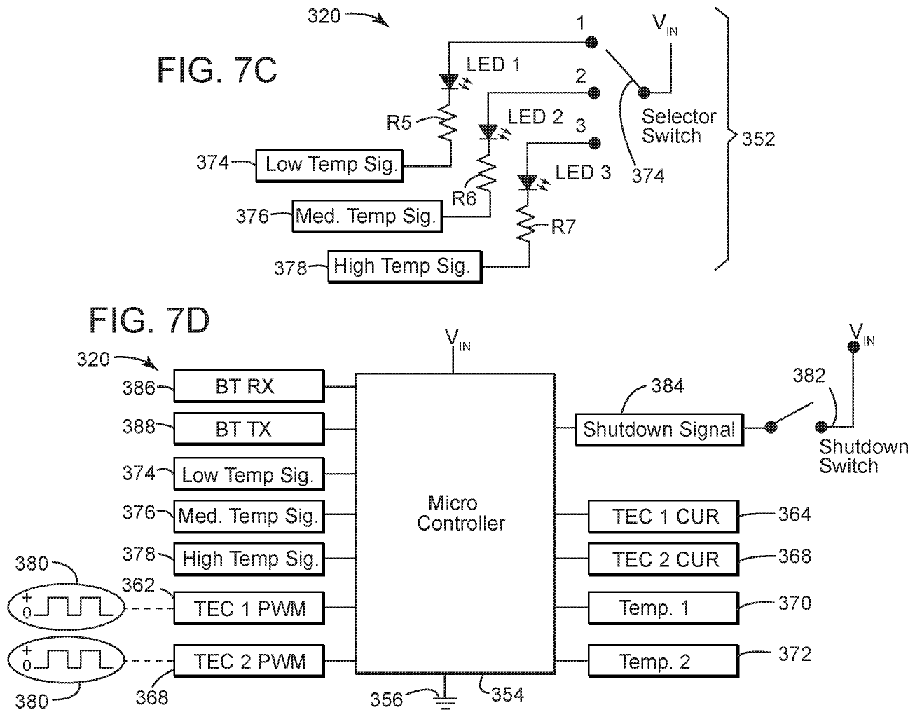

The TEC headband 300 also includes a flexible printed circuit board (PCB) 318 that is also connected to the batteries 316. The flexible PCB 318 provides a supporting structure for a control system 320 (see FIGS. 7A-7D) that is disposed on the flexible PCB 318. The flexible PCB 318 is resilient enough to conform to a user's forehead when a user 330 is wearing the TEC headband 300 and strong enough to support interconnections and components of the control system 320 that are mounted on the PCB 318.

Though a flexible PCB 318 is illustrated in FIG. 3 to support the control system 320, other support structures may be used to do the same. For example, the control system 320 may be mounted on a plurality of smaller rigid printed circuit boards located on opposing side of the TEC headband and hardwired together.

The TEC headband 300 also includes a housing 322 that is operable to contain the pair of TEC devices 302, 304, the pair of heat sinks 306, 308, the flexible PCB 318, the batteries 316, the thermal spreader plates 312, the interface layer frames 314 and the control system 320. The housing 322 is flexible enough to conform to a user's forehead when the TEC headband 300 is worn by a user 330.

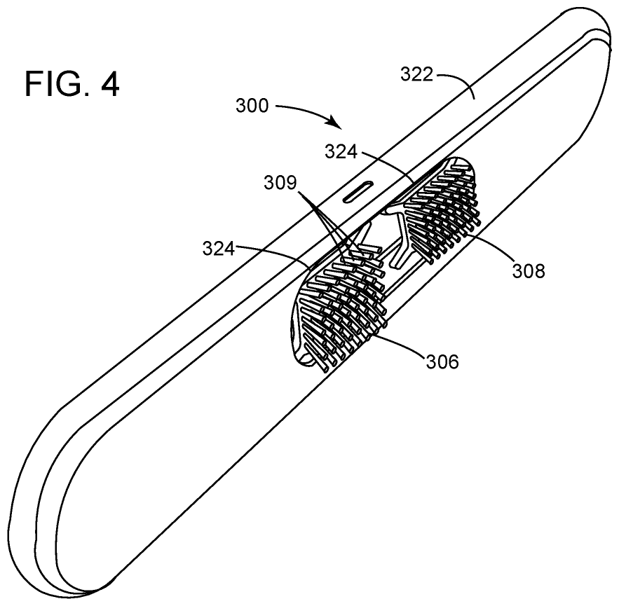

Referring to FIG. 4, an example is depicted of a perspective view of the TEC headband 300 of FIG. 3 assembled within the housing 322, in accordance with aspects described herein. In order to enhance heat transfer from the fins 309 to the atmosphere, to fins 309 of the heat sinks 306, 308 project outwardly from a pair of apertures 324 that are disposed in the housing 322.

The housing 322, in this example, contains all components of the TEC headband 300. Alternatively, certain components may be located outside of the housing 322. For example, the control system 320 (see FIGS. 7A-7D) may be located in a separate control system housing (not shown) located on a flexible connecting strap (see FIG. 5) that is attached to the distal ends of the housing 322. In that case, when a user 330 wears the TEC headband 300, the housing 322 would be positioned over the user's forehead and the control system housing would be positioned on the side of a user's head proximate the user's temples.

Referring to FIG. 5, an example is depicted of a perspective view of a TEC headband 300 fit around a user's head and having a fan 328 for flowing air 332 over the pair of heat sinks 306, 308 to enhance the transfer of heat from the heat sinks 306, 308 to the atmosphere, in accordance with aspects described herein. The TEC headband 300 fits around the head of a user 330. A connecting strap 326 is attached to the distal ends of the housing 322 and is sized to securely fit the TEC headband 300 to the head of a user 330. The connecting strap 326 may be elastic in order to snuggly fit to a user's head. Alternatively, the strap 326 may an inelastic fabric or other flexible material (such as leather) that is adjustably attachable to a user via a buckle, hook and loop fasteners or other fastening system.

A fan 328, or other air moving device, may be mounted on the housing 322 or connecting strap 326. The fan may flow air 332 over the fins 309 of the heat sinks 306, 308 in order to enhance heat transfer from the heat sinks 306, 308 to the atmosphere.

Referring to FIG. 6, an example is depicted of a perspective view of the TEC headband 300 fit around a head of a user 300 and having the TEC devices 302, 304 positioned directly over supratrochlear 334 and supraorbital 336 arties on either side of the forehead of a user 330, in accordance with aspects described herein. When the user 330 is wearing the TEC headband 300, the TEC device 302, 304 are positioned directly over the supratrochlear arteries 334 and supraorbital arteries 336. By applying cooling to the supratrochlear and supraorbital arteries 334, 336, the pain of a migraine headache is more efficiently alleviated.

Referring to FIGS. 7A, 7B, 7C and 7D, an example is depicted of a simplified schematic the battery 316 connected to the control system 320 of the TEC headband 300. As illustrated in FIG. 7A, the control system 320 may include a power on/off control system 340, a battery protection control system 342, a voltage regulator system 344 and a pair of TEC driver circuits 346, 348 for each TEC device 302, 304, in accordance with aspects described herein. As illustrated in FIG. 7B, the control system 320 may also include a temperature detection circuit 350, in accordance with aspects described herein. As illustrated in FIG. 7C, the control system 320 may also include a temperature setting selector circuit 352, in accordance with aspects described herein. As illustrated in FIG. 7D, the control system 320 may also include a microcontroller 354, in accordance with aspects described herein.

As an overview, one of the primary functions of the control system 320 may be temperature control of the TEC devices 302, 304. The temperature control function may be achieved by, for example, open or closed loop control.

The temperature control function of the control system 320 may be to provide a constant and regulated temperature to the forehead of a user 330 by means of controlling the power to the two TECs 302, 304. To do this, the control system may be made aware of either the desired temperature or the appropriate TEC power setting that will achieve the desired temperature, both as determined by the user through either buttons on the TEC headband 300 or through a remote communication device (not shown).

In an open loop temperature control system, the control system 320 may be “unaware” of the actual temperature of the device being controlled, meaning there may be no sensor or other component that provides the control system with a true measure of the actual temperature. Through analysis and experimentation during the design effort, the relationship between power to the temperature device(s) (such as, for example, the TEC device 302, 304) and the actual temperature achieved is established. During normal operation, to achieve the desired temperature, the control system may provide the appropriate power setting that was previously determined to achieve that desired temperature.

In the example of an open loop system, the power level to the TEC devices 302, 304 may be set, not on the basis of specific desired temperatures, but instead on the real time comfort level being experienced by the user 330. In essence the user may “close the loop” in the open loop control system. The user 330 may adjust the power level (warmer of colder) on the TEC headband 200 until the user experiences the desired comfort level. This may be done without regard to the actual temperature of the TEC devices 302, 304.

In a closed loop temperature control system, at least one sensor for measuring temperature is connected to the control system. In this example, the control system 320 may be aware of both the desired temperature as set by the user 330 and the actual temperature as measured by the sensor (for example thermistors 358 and 360). The control system 320 may substantially constantly compare the desired temperature with the actual temperature and calculate an error value which is the difference between the two. If the error value is greater than zero, the actual temperature may be colder than the desired temperature. Conversely, if the error value is less than zero, the actual temperature may be warmer than the desired temperature. Using this error value, the control system may substantially continually adjust the power to the TEC devices 302, 304 to achieve and maintain the actual temperature at the desired temperature setting.

The methods by which the error value may be used to control the power to the TEC devices 302, 304 may vary from the basic to the sophisticated. In an example of a basic method, if the error signal indicated that the TEC device 302, 304 temperature was warmer than the desire temperature, the control system 320 may apply full power to the TEC devices. If the sensor indicated that the TEC was colder than the desired temperature, the control system may disconnect power to the TEC devices. Since the control system 320 may continually measure the actual temperature at a rate higher than the thermal response time of the TEC devices, the net effect is that the power may be modulated to the TEC devices in a type of “pulse width modulation”, PWM. This exemplary method is often referred to colloquially as a “bang-bang” method of control because the power to the TEC devices continually moves from one extreme to the other, i.e. it is either on or off

An example of a more sophisticated method of closed loop temperature control is to employ a PID control loop. “PID” refers to three different arithmetic formulas that are applied to the error value. The “P” term corresponds to the “proportional” relationship between the desired and actual temperatures. In a PID loop where only a P term is used, power is applied to the temperature device in proportion to the magnitude of the error values. In practice and for TEC device control, the warmer the TEC device is in comparison to the desired setpoint, the more power is applied to the TEC device. As the desired and actual temperatures get closer to each other, the power to the TEC device is proportionally reduced.

The “I” term in a PID control loop refers to the “integral” relationship between the desired and actual temperatures. In practice and for TEC device control, the longer the desired temperature is warmer than the actual temperature, the greater the power applied to the TEC device.

The “D” term in a PID control loop refers to the “derivative” relationship between the desired and actual temperatures. In practice and for TEC device control, the faster that the TEC is becoming warmer than the desired setpoint, the greater the power applied to the TEC.

In a PID control loop, it may not always be necessary to employ all three terms. Each application determines which terms are necessary and the degree to which each is applied.

The advantage of a closed loop PID method of control is that more precise temperature control may be achieved relative to more basic control methods. This method may also be more efficient, meaning that overall, less power is consumed by the control system than with open loop or “bang-bang” methods of control.

Referring specifically to FIG. 7A, the battery protection system 342 may protect the battery 316 from such things as the battery being forced to operate when it is too cold or too hot. The battery protection system 342 may also protect the battery 316 from being installed backwards. The battery protection system 342 may include an array of mosfets, capacitors and resistors properly wired to provide the appropriate protection.

The power on/off control system 340 may include a simple on/off switch. The system 340 may also be sending and receiving signals from the microcontroller 354 to effect a timed shutdown or start-up procedure.

The voltage regulator 344 regulates the battery voltage (Vbattery) to produce a regulated input voltage (Vin) to such components and system as the microcontroller 354, the temperature detection circuit 350 and the temperature setting selector circuit 352. The regulator 344 may be, for example, a switching voltage regulator, which provides a regulated 5 volt output. The voltage regulator may, for example, have the part number XC9142C50DMR-G and be manufactured by Torex Semiconductor located in Tokyo, Japan.

The TEC driver circuit 346 may include a field effect transistor FET (Q1) having its drain (D) and source (S) wired in parallel with diode (D1). The drain (D) of FET (Q1) may also be connected to resistor R1, which is connected to the low side of TEC device 302. The source (S) of FET (Q1) may also be connected to a system ground 356. As will be explained in greater detail herein, the gate (G) of the FET (Q1) may be receiving a pulse width modulated signal 362 (TEC1PWM) from the microcontroller 354, which switches the FET (Q1) on and off to regulate the current flow through the TEC device 302. Additionally, the source (S) of FET (Q1) may be providing a current signal 364 (TEC1CUR) which represents the current flow through TEC device 302 and transmits that signal to microcontroller 354.

The TEC driver circuit 348 may include a field effect transistor FET (Q2) having its drain (D) and source (S) wired in parallel with diode (D2). The drain (D) of FET (Q2) may also be connected to resistor R3, which is connected to the low side of TEC device 304. The source (S) of FET (Q2) may also be connected to the system ground 356. As will be explained in greater detail herein, the gate (G) of the FET (Q2) may be receiving a pulse width modulated signal 366 (TEC2PWM) from the microcontroller 354, which switches the FET (Q2) on and off to regulate the current flow through the TEC device 304. Additionally, the source (S) of FET (Q2) may be providing a current signal 368 (TEC2CUR) which represents the current flow through TEC device 304 and transmits that signal to microcontroller 354.

Referring specifically to FIG. 7B, the temperature detection circuit 350 may include a thermistor 358, which is placed on TEC device 302 in order to measure its temperature setting. Also, the temperature detection circuit 350 may include a thermistor 360, which is placed on TEC device 304 in order to measure its temperature setting. Temperature detection circuit 350 may generate a temperature signal 370 (Temp. 1) which represents the measured temperature setting of TEC device 302. Temperature detection circuit 350 may also generate a temperature signal 372 (Temp. 2) which represents the measured temperature setting of TEC device 304.

Referring specifically to FIG. 7C, the temperature setting selector circuit 352 may include a three-position selector switch 374. With selector switch 352 in the first position, Vin is connected to LED 1 and R5, which generates low temp signal 374 that is transmitted to the microprocessor 354. With selector switch 352 in the second position, Vin is connected to LED 2 and R6, which generates medium temp signal 376 that is transmitted to the microprocessor 354. With selector switch 352 in the third position, Vin is connected to LED 3 and R7, which generates high temp signal 378 that is transmitted to the microprocessor 354.

Though the temperature setting selector circuit illustrated in FIG. 7C shows three temperature settings, any number of temperature setting are within the scope of this disclosure. For example, a vernier system may be used to set any temperature setting within a given range.

The temperature settings may be set above the skin temperature of a user but above the freezing temperature of 32 degrees Fahrenheit. For example, the temperature settings can be set within a range of 50 to 75 degrees Fahrenheit (F) or within a range of 60 to 70 degrees F. The temperature settings can also be adjustably set to make sure that they remain above the dew point temperature for a given day, in order to prevent condensation.

Referring specifically to FIG. 7D, the microcontroller 354 contains one or more central processing units (CPUs) along with memory that is operable to store executable program instructions and programmable input/output peripherals. The microcontroller 354 receives:

the current measurement signal 364 (TEC1CUR) representing measured current flow through TEC device 302,

the current measurement signal 368 (TEC2CUR) representing measured current flow through TEC device 304,

the temperature signal 370 (Temp. 1) representing the measured temperature setting of TEC device 302, and

the temperature signal 372 (Temp 2) representing the measured temperature setting of TEC device 304.

Additionally, the microcontroller 354 receives one of the low temp signal 374, medium temp signal 376 or high temp signal 378 selected with selector switch 374. The above signals provide information that enables the microcontroller 354 to control and regulate the temperature settings of the TEC devices 302 and 304.

The microcontroller 354 may regulate the temperature of the TEC devices 304 by generating the pulse width modulated signals 362 (TEC1PWM) and 368 (TEC 2 PWM). Essentially, the more current that flows through the TEC devices 302, 304, the greater the Peltier cooling effect. The longer FETs Q1 and Q2 are switched on, the more current that will conduct through the TEC devices 302, 304 to ground 356 and the greater the cooling effect. Since the signals 362 (TEC1PWM), 368 (TEC2PWM) control the frequency of switching of Q1 and Q2, they also control the current flow through TEC devices 302, 304 and the magnitude of the cooling effect provided by each.

If the microcontroller 354 provides a constant DC current for both signals 362 (TEC1PWM) and 368 (TEC2PWM), the FETs Q1 and Q2 will remain open indefinitely and the maximum amount of current will flow through TEC devices 302 and 304 for a maximum cooling effect. This may be the case when the selector switch is set to the first position and generates low temp signal 374.

If the signals 362, 368 are pulse width modulate for a 50 percent duty cycle (represented by diagrams 380), the FETs Q1 and Q2 will be on for half the time and off for half the time. Accordingly, an average of half the maximum current will flow through TEC devices 302 and 304 for a medium cooling effect. This may be the case when the selector switch is set to the second position and generates medium temp signal 376.

If the signals 362, 368 are pulse width modulate for a 25 percent duty cycle (represented by diagrams 380), the FETs Q1 and Q2 will be on for a 25% of the time and off for 75% of the time. Accordingly, an average of 25% of the maximum current will flow through TEC devices 302 and 304 for the least amount of cooling effect (i.e., for the highest temperature setting). This may be the case when the selector switch is set to the third position and generates high temp signal 376

If the microcontroller 354 provides a zero current for both signals 362 (TEC1PWM) and 368 (TEC2PWM), the FETs Q1 and Q2 will remain closed indefinitely and zero current will flow through TEC devices 302 and 304, which will effectively shut the TEC devices 302 and 304 down.

Shutdown switch 382 may be used to provide a shutdown signal 384 to the microcontroller 354. However, it is important to note that if the power though the TEC devices 302 and 304 is shut down (by either reducing the operating current, the operating voltage or both) to zero when the temperature differential across the heating plate 108 and cooling plate 106 (see FIG. 1) is great, then the heating and cooling plates 108, 106 may rapidly equalize in temperature. This means that the cooling plate 106 may get uncomfortably warm for a user 330 if the TEC devices were operating at a low cooling temperature and the shutdown of power was immediate.

Advantageously, upon a shutdown signal 384 for the TEC devices 302, 304, the microcontroller 354 is operable to reduce the power through each TEC device 302, 304 from its operating power at the time of receiving the shutdown signal 384 to zero power over a predetermined shutdown time period, in order to prevent rapid heating of the cooling plates 106 of each TEC device 302, 304. One way the microcontroller can accomplish this is to reduce the duty cycle of the pulse width modulated signal 376, 378 supplied to each TEC driver circuit 346, 348 over the predetermined shutdown time period in order to reduce the current flow to zero for each TEC device. The predetermined shutdown time period may be 5 seconds or greater, 15 seconds or greater, 30 second or greater, 45 seconds or greater, or 60 second or greater.

It is important to note that in this example, the power through the TEC devices 302, 304 is reduced by gradually reducing the current flow through the TEC device. However, it is within the scope of this invention that the power through the TEC devices 302, 304 may be reduced by gradually reducing the operating voltage of the TEC device as well.

In the case of a closed loop control system, another way the microcontroller 354 and/or control system 320 may gradually reduce power to the TEC devices 302, 304 may be to change the desired temperature setpoint from the initial setpoint to the ambient temperature. The closed loop control system will gradually reduce the power to the TEC devices 302, 304 to bring the temperature of the cooling plates 106 of the TEC devices up to ambient temperature over time (e.g., in 5 seconds or greater), until little to no current and/or power is consumed by the TEC devices.

The microcontroller 354 may also be in communication with the power on/off system 340 during the shutdown time period. Wherein, when the current to the TEC devices 302 and 304 is reduced to zero, the microcontroller may send a signal (not shown) to the power on/off control, which shut the power off to the control system 320 by disconnecting the battery 316 from the control system 320.

The microcontroller is also capable of transmitting a bluetooth receive signal 386 (BTRX) and a bluetooth transmit signal 388 (BTTX). The blue tooth receive and transmit signals 386, 388 can be used to transmit to another device, such as a cell phone or a computer, that has a software application install thereon. The software application may be capable of remotely operating the TEC headband 300. The software application may also be capable of storing and processing data received from the TEC headband 300 for such purposes as: tracking frequency of use by a user, tracking temperature setting usually used by the user and more.

Though the control system 320 has been described with reference to the examples provided and illustrated in FIGS. 7A-7D, numerous other configurations of the control system 320 are also within the scope of this disclosure. For example, the designs of the battery protection system 342, the power on/off control system 340, the voltage regulator system 344, TEC driver circuits 346, 348, the temperature detection circuit 350, the temperature setting selector circuit 352, and the microcontroller system 354 may all change to meet various design parameters for different embodiments of the TEC headband 300.

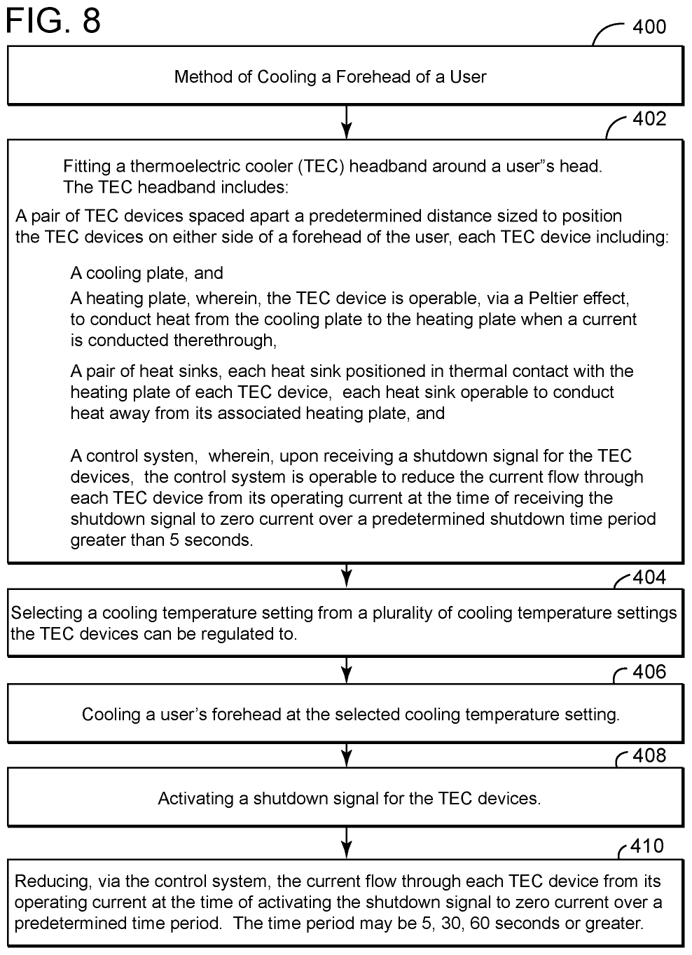

Referring to FIG. 8, an example is depicted of a flow diagram 400 of a method of cooling a forehead of a user in accordance with one or more aspects of the present disclosure. The method at step 402 includes fitting a thermoelectric cooler (TEC) headband operable around a user's head. The TEC headband includes:
a pair of TEC devices spaced apart a predetermined distance sized to position the TEC devices on either side of a forehead of the user, each TEC device including:
   a cooling plate, and
   a heating plate,
   wherein, the TEC device is operable, via a Peltier effect, to conduct heat from the cooling plate to the heating plate when a current is conducted therethrough,
a pair of heat sinks, each heat sink positioned in thermal contact with the heating plate of each TEC device, each heat sink operable to conduct heat away from its associated heating plate, and
a control system, wherein, upon receiving a shutdown signal for the TEC devices, the control system is operable to reduce the current flow through each TEC device from its operating current at the time of receiving the shutdown signal to zero current over a predetermined shutdown time period greater than 5 seconds.

At 404 of the method, a cooling temperature setting is selected from a plurality of cooling temperature settings the TEC devices can be regulated to.

AT 406 of the method, a user's forehead is cooled at the selected cooling temperature setting.

At 408 of the method, a shutdown signal for the TEC devices is activated.

At 410 of the method, the control system reduces the current flow through each TEC device from its operating current at the time of activating the shutdown signal to zero current over a predetermined time period. The time period may be 5 second, 30 seconds, 60 second or greater.

It should be appreciated that all combinations of the foregoing concepts and additional concepts discussed in greater detail herein (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein.

Although the invention has been described by reference to specific examples, it should be understood that numerous changes may be made within the spirit and scope of the inventive concepts described. Accordingly, it is intended that the disclosure not be limited to the described examples, but that it have the full scope defined by the language of the following claims.

What is claimed is:

1. A thermoelectric cooler (TEC) headband operable to fit around a user's head, the TEC headband comprising:
a pair of TEC devices spaced apart a predetermined distance sized to position the TEC devices on either side of a forehead of the user, each TEC device comprising:
a cooling plate, and
a heating plate,
wherein, the TEC device is operable, via a Peltier effect, to conduct heat from the cooling plate to the heating plate when a current is conducted therethrough;
a pair of heat sinks, each heat sink positioned in thermal contact with the heating plate of each TEC device, each heat sink operable to conduct heat away from its associated heating plate; and
a housing operable to contain the pair of TEC devices and pair of heat sinks;
wherein, the TEC headband is operable to cool the user's forehead when placed thereon.

2. The TEC headband of claim 1, wherein each TEC device comprises:
alternating n-type and p-type semiconductor pillars electrically connected in series, the semiconductor pillars positioned thermally in parallel between the cooling plate and heating plate.

3. The TEC headband of claim 1, wherein the predetermined distance is sized to position the TEC devices over the supratrochlear and supraorbital arteries on either side of the user's forehead.

4. The TEC headband of claim 1, comprising:
a pair of thermal spreader plates positioned in thermal contact with the cooling plate of each TEC device, each thermal spreader plate having a surface area larger than a surface area of it associated cooling plate, each thermal spreader plate operable to cool a larger area than its associated cooling plate, when the TEC headband is worn by a user.

5. The TEC headband of claim 1, comprising:
a fan operable to flow air over the pair of heat sinks to enhance the transfer of heat from the heat sinks to the atmosphere.

6. The TEC headband of claim 1, comprising:
a battery operable to supply power to the TEC devices and to fit within the housing.

7. The TEC headband of claim 6, comprising:
a control system operable to receive power from the battery,
wherein the control system enables the user to select a cooling temperature setting from a plurality of cooling temperature settings the TEC devices can be regulated to.

8. The TEC headband of claim 7, wherein the control system comprises:
a microcontroller electrically connected to the battery, the microcontroller operable to measure and control the temperature of the TEC devices.

9. The TEC headband of claim 8, wherein the control system comprises:
a pair of TEC driver circuits, each TEC driver circuit connected to the microcontroller and an associated TEC device;
wherein the microcontroller switches the TEC driver circuits on and off to control the amount of current conducted through each TEC device, the amount of current conducted through each TEC device regulating the temperature setting of each TEC device.

10. The TEC headband of claim 9, wherein the microcontroller supplies a pulse width modulated signal to each TEC driver circuit to control the amount of current conducted through each TEC device.

11. The TEC headband of claim 10, wherein, upon a shutdown signal for the TEC devices, the microcontroller is operable to reduce the power through each TEC device from its operating power at the time of receiving the shutdown signal to zero power over a predetermined shutdown time period greater than 5 seconds, in order to prevent rapid heating of the cooling plates of each TEC device.

12. The TEC headband of claim 11, wherein the microcontroller reduces the duty cycle of the pulse width modulated signal supplied to each TEC driver circuit over the predetermined shutdown time period in order to reduce the current flow to zero for each TEC device.

13. A thermoelectric cooler (TEC) headband operable to fit around a user's head, the TEC headband comprising:
a pair of TEC devices comprising:
a cooling plate, and
a heating plate,
wherein, the TEC device is operable, via a Peltier effect, to conduct heat from the cooling plate to the heating plate when a current is conducted therethrough;
a pair of heat sinks, each heat sink positioned in thermal contact with the heating plate of each TEC device, each heat sink operable to conduct heat away from its associated heating plate;
a control system, wherein, upon receiving a shutdown signal for the TEC devices, the control system is operable to reduce the power through each TEC device from its operating power at the time of receiving the shutdown signal to zero power over a predetermined shutdown time period greater than 5 seconds.

14. The TEC headband of claim 13, wherein the pair of TEC devices are spaced apart a predetermined distance sized to position the TEC devices on either side of a forehead of the user.

15. The TEC headband of claim 14, wherein the predetermined distance is sized to position the TEC devices over the supratrochlear and supraorbital arteries on either side of the user's forehead.

16. The TEC headband of claim 13, comprising:
a fan operable to flow air over the pair of heat sinks to enhance the transfer of heat from the heat sinks to the atmosphere.

17. The TEC headband of claim 13, wherein the control system enables the user to select a plurality of cooling temperature settings the TEC devices will be regulated to.

18. The TEC headband of claim 13, comprising:
a battery operable to supply power to the TEC devices and to fit within the housing; and
the control system comprising:
a microcontroller electrically connected to the battery, and
a pair of TEC driver circuits, each TEC driver circuit connected to the microcontroller and an associated TEC device;
wherein the microcontroller switches the TEC driver circuits on and off to control an amount of current conducted through each TEC device.

19. The TEC headband of claim 18, wherein the microcontroller reduces the duty cycle of a pulse width modulated signal supplied to each TEC driver circuit over the predetermined shutdown time period in order to reduce the current flow to zero for each TEC device.

20. A method of cooling a forehead of a user comprising:
fitting a thermoelectric cooler (TEC) headband operable around a user's head, the TEC headband comprising:
a pair of TEC devices spaced apart a predetermined distance sized to position the TEC devices on either side of a forehead of the user, each TEC device comprising:
a cooling plate, and
a heating plate,
wherein, the TEC device is operable, via a Peltier effect, to conduct heat from the cooling plate to the heating plate when a current is conducted therethrough,
a pair of heat sinks, each heat sink positioned in thermal contact with the heating plate of each TEC device, each heat sink operable to conduct heat away from its associated heating plate, and
a control system, wherein, upon receiving a shutdown signal for the TEC devices, the control system is operable to reduce the power through each TEC device from its operating power at the time of receiving the shutdown signal to zero power over a predetermined shutdown time period greater than 5 seconds;
selecting a cooling temperature setting from a plurality of cooling temperature settings the TEC devices can be regulated to;
cooling a user's forehead at the selected cooling temperature setting; and
activating a shutdown signal for the TEC devices, wherein the control system reduces the power through each TEC device from its operating power at the time of activating the shutdown signal to zero power over the predetermined time period.
